(19) United States
(12) Patent Application Publication
(10) Pub. No.: US 2012/0315727 A1
(43) Pub. Date: Dec. 13, 2012

(54) Thin Power Package

(75) Inventors: Jiangyuan Zhang, Shanghai (CN); Elite Lee, Shanghai (CN); Dana Liu, Shanghai (CN)

(73) Assignee: SHANGHAI KAIHONG ELECTRONIC COMPANY LIMITED, Shanghai (CN)

(21) Appl. No.: 13/158,229

(22) Filed: Jun. 10, 2011

(51) Int. Cl. H01L 21/78

(52) U.S. Cl. 438/112; 257/E21.599

(57) ABSTRACT

In one embodiment, a method for manufacturing a power semiconductor package is provided. The method includes attaching a plurality of solders balls onto a power semiconductor device. The plurality of solder balls are attached onto a lead frame using a flip bond processing step. The flip bond processing step bonds the semiconductor device to the lead frame and interconnects the lead frame to the semiconductor device in a single processing step. The semiconductor device, plurality of solder balls, and the lead frame are molded to form the power semiconductor package, wherein semiconductor device is exposed on a first side of the semiconductor package.

### BACKGROUND

Particular embodiments generally relate to power semiconductor devices.

Power semiconductor devices may be used in a wide variety of applications, such as in electric power, metallurgy, equipment manufacture, traffic, and national defense applications. Power semiconductor devices are also used in energy and laser applications. As long as there is electrical power usage, a power semiconductor device may be used. Recently, power semiconductor manufacturing techniques have moved towards the direction of high-current, high-pressure, and high-frequency integration and intelligization.

As a result of the above manufacturing techniques, the power semiconductor die size and package size have increased. This runs counter to a thin, small, and light trend in package development. Also, package resistance and thermal resistance have increased, which affects the production performance of the power semiconductor device.

### SUMMARY

In one embodiment, a method for manufacturing a power semiconductor package is provided. The method includes attaching a plurality of solders balls onto a power semiconductor device. The plurality of solder balls are attached onto a lead frame using a flip bond processing step. The flip bond processing step bonds the semiconductor device to the lead frame and interconnects the lead frame to the semiconductor device in a single processing step. The semiconductor device, plurality of solder balls, and the lead frame are molded to form the power semiconductor package, wherein semiconductor device is exposed on a first side of the semiconductor package.

In one embodiment, a top mold chase is used to mold the semiconductor package, wherein the top mold chase includes a flat surface that is facing the semiconductor device.

In one embodiment, a bottom mold chase is placed beneath the lead frame to form a cavity in which encapsulation is injected to mold the semiconductor package.

In one embodiment, a method for manufacturing a power semiconductor package is provided. The method includes bonding the plurality of solder balls onto a lead frame using a flip bond processing step. The flip bond processing step bonds the semiconductor device to the lead frame and interconnects the lead frame to the semiconductor device in a single step. A first mold chase is placed above a power semiconductor device, wherein the first mold chase has a flat surface facing a bottom surface of the semiconductor device. A second mold chase is placed below a bottom surface of a lead frame. A molding compound is inserted in a cavity formed by the first mold chase and the second mold chase to encapsulate the semiconductor device, plurality of solder balls, and the lead frame to form a semiconductor package. The semiconductor device is exposed on a first side of the semiconductor package.

In one embodiment, wire bonding and die bonding are performed in the flip bond processing step.

In one embodiment, the lead frame is exposed on a second side of the semiconductor package.

The following detailed description and accompanying drawings provide a better understanding of the nature and advantages of the present invention.

### BRIEF DESCRIPTION OF THE DRAWINGS

FIG. 1 depicts a flowchart of a method for manufacturing a power semiconductor device package according to one embodiment.

FIGS. 2a and 2b depict processing steps 01 and 02 in more detail.

FIGS. 3a and 3b describe the flip bond processing step in more detail.

FIG. 4 depicts a more detailed example of molding manufacturing process according to one embodiment.

FIGS. 5a and 5b depict the trim and form manufacturing process in more detail according to one embodiment.

FIG. 6 shows a side view of package according to one embodiment.

### DETAILED DESCRIPTION

Described herein are techniques for a thin power package. In the following description, for purposes of explanation, numerous examples and specific details are set forth in order to provide a thorough understanding of embodiments of the present invention. Particular embodiments as defined by the claims may include some or all of the features in these examples alone or in combination with other features described below, and may further include modifications and equivalents of the features and concepts described herein.

Particular embodiments provide an inverted encapsulation structure and encapsulation method thereof that results in a very thin package which can satisfy the heat dissipation requirements of the chip.

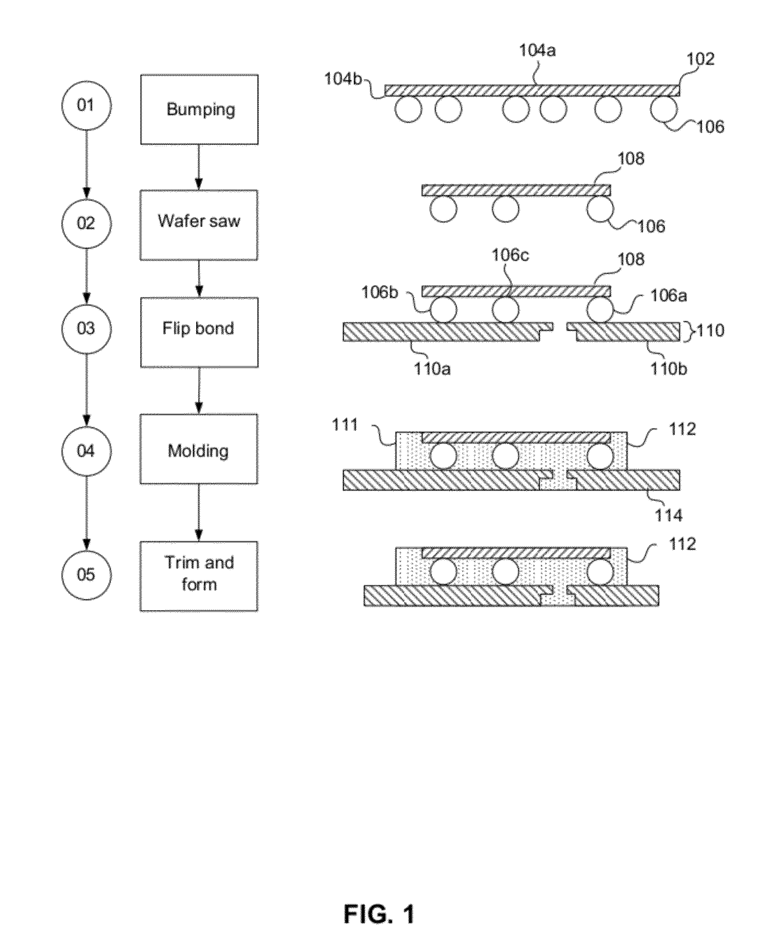

FIG. 1 depicts a flowchart of a method for manufacturing a power semiconductor device package according to one embodiment. At 01, a bumping processing step is performed. In the bumping processing step, a wafer 102 includes a bottom surface 104a and a top surface 104b. A plurality of solder balls (e.g., conductive lugs) 106 are attached to top surface 104b. In one embodiment, solder balls may be composed of copper (Cu), tin, and stannum. Also, gold (Au) may be included.

The forming of a plurality of solder balls may be on the surface of bonding pads. At least one conductive lug is formed on the surface of each bonding pad, which can ensure that an effective electrical connection is formed between succeeding bonding pads and the base pins of the lead wire frame; increasing the number of conductive lugs on the surface of each bonding pad can also further enhance the reliability of the electrical connection.

At 02, a wafer saw processing step is performed. The wafer saw processing step saws wafer 102 into individual semiconductor devices (e.g., semiconductor dies) 108. Semiconductor device 108 may be an integrated circuit computer chip.

The chip may be any common type of chip in the field, including a memory device, logic circuit or power device etc. The method described is capable of accounting for both the device dimensions and its encapsulation insulation properties, and thus is particularly suited to power devices.

The chip can also be a single chip already cut off from the whole wafer, or it may be one chip of an as yet uncut intact wafer possessing multiple individual chips. In the case of a chip existing inside an intact wafer, a cutting step should be included i.e. dividing the intact wafer into multiple individual chip structures by means of cutting. During implementation, it is possible to first form solder balls for the bonding pads on all chips of the entire wafer, and then cut the wafer to produce multiple individual chips, or the cutting may be performed first, followed for the forming of the conductive lugs. The specific process used in the wafer cutting step may utilize any common means in the field, for example, a diamond knife, grinding wheel or laser cutting, and is not further elaborated here.

At 03, a flip bond processing step is performed. The flip bond processing step performs a die bond process and a wire bond process in a single step. The flip bond is used to bond solder balls 106 onto a lead frame 110 using a flux. For example, a first solder ball 106a is bonded to the lead frame 110b. Also, solder balls 106b and 106c are bonded to a lead frame 110a. Other solder balls 106 not shown may also be bonded to lead frame 110. In one embodiment, pads are formed on wafer 102 and solder balls 106 are bonded to the pads. The flip bond step bonds the semiconductor device to lead frame 110. Also, the flip bond creates an interconnection between semiconductor device and lead frame 110 through solder balls 106. The bonding of the semiconductor device and the interconnection is performed in one step.

The flip bond process is performed by flipping semiconductor device 108 such that top surface 104b is facing down and bottom surface 104a is facing up. Solder balls are facing lead frame 110. The wire bonding and die bonding process is performed in the flip bond process step and thus reduces process steps that need to be performed. Conventionally, a die bonding process is performed to bond the semiconductor device to the lead frame and then a wire bonding process is performed to bond wires from the lead frame to the die. This combines the two steps in a flip bonding process to manufacture a power package.

This step adopts the method whereby the solder balls are directly welded to lead frame 110; this both omits the need for a chip base, reducing the volume of the resulting product, and also combines the welding and routing steps used in conventional inverted welding processes into one step, shortening the process period. In addition, adopting the method of directly bonding the solder balls to lead frame 110, in comparison with the use of metal lines (e.g. gold lines) to electrically connect the two together reduces the electrical resistance between lead frame 110 and the chip.

A further advantage of this step is that by using solder balls in place of metal lines, the lead wire separation between the chip and lead frame 110 is shortened, avoiding creepage and crosstalk among the lead wires and the effect of external electromagnetic radiation on the working of the chip, and thus is particularly suited to the encapsulation of high frequency devices.

At 04, a molding processing step is performed. A molding machine may be used to mold a package 112 that encapsulates semiconductor device 108, solder balls 106, and lead frame 110. As will be described in more detail below, a top mold chase 114 has a flat surface. Top mold chase 114 is coupled to a bottom mold chase 116. Although not shown, a film between package 112 and top mold chase 114 is provided. The film prevents molding flash.

The molding compound in this step should at least wrap the front surface of the chip and the solder balls, thereby joining lead frame 110, chip and solder balls together as one entity, and plastically sealing the chip front surface and solder balls, preventing their exposure to oxidation and contamination from the air.

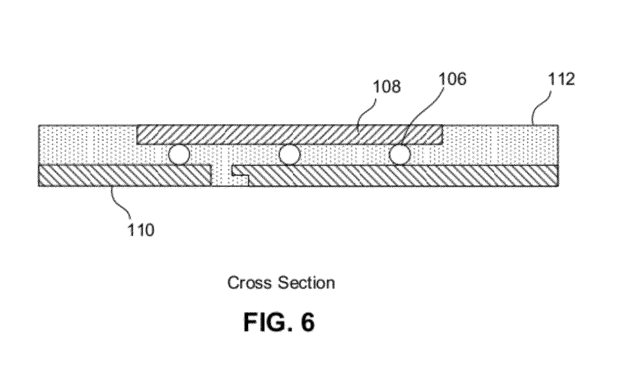

In one embodiment, the back surface of the chip is not enclosed by the plastic body, but is exposed to the air. Because the chip back surface does not have any circuit structure or devices, it is impervious to oxidation or contamination, and the advantage of exposing it to the air lies in facilitating external heat dissipation during the operation of the chip. The intention is to obtain the structure illustrated in FIG. 6; during the injection molding step, the cavity of the injection mold and the back surface of the chip should be bonded together, thus ensuring that the molding compound will not cover the chip back surface during the injection molding process.

In another embodiment, a relatively deep mold cavity may be utilized such that there is a gap between the back surface of the chip and the mold cavity, where the width of the gap for example may be less than 100 microns; its minimum width depends on the minimum permitted gap width during injection molding, e.g. 5 microns, so as to ensure that insulating glue is adequate to fill the spaces. The advantage of preserving a gap between the two lies in enabling the chip to be more strongly secured inside the plastic body, and does not slide relative to the lead wire frame due to the exposure of the back surface, or actually detach itself from the plastic body. However, to allow heat dissipation of the chip, the gap between the plastic body and the chip back surface should be as small as possible whilst still enabling the proper performance of injection molding, thereby ensuring that the chip is able to release heat energy to the external environment through its back surface.

At 05, a trim and form processing step is performed. A trim and form machine may be used to shape package 112 into a desired form and/or a single package.

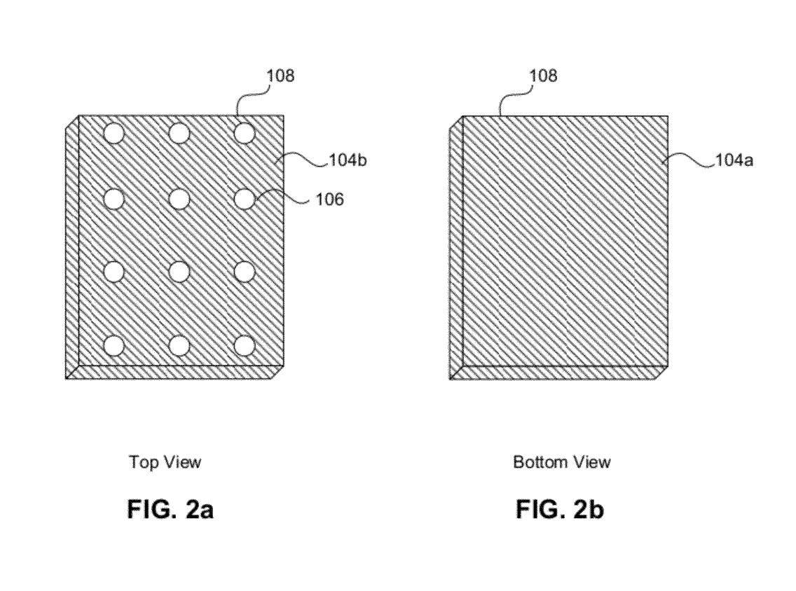

The above process steps will be described in more detail below. FIGS. 2a and 2b depict processing steps 01 and 02 in more detail. FIG. 2a shows a top view of semiconductor device 108 according to one embodiment. Solder balls 106 have been attached to top surface 104b. FIG. 2b shows a bottom view of semiconductor device 108 according to one embodiment. As shown, solder balls 106 are not attached to bottom surface 104a.

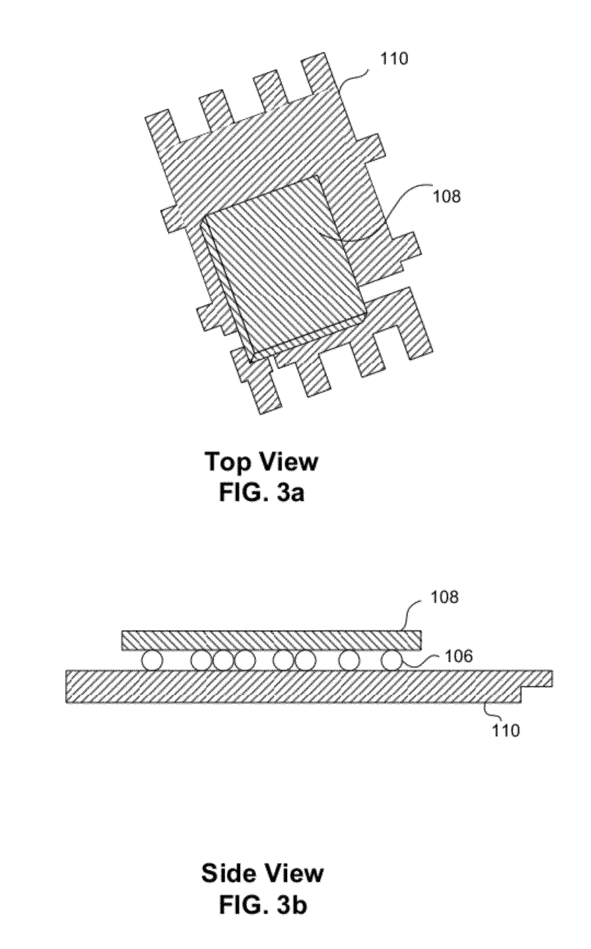

FIGS. 3a and 3b describe the flip bond processing step in more detail. FIG. 3a shows a top view of semiconductor device 108 and lead frame 110. Bottom surface 104a is facing up or away from lead frame 110.

FIG. 3b shows a side view of the result of the flip bond manufacturing process. As shown, semiconductor device 108 has been bonded to lead frame 110 via solder balls 106. Top surface 104b and solder balls 106 are facing lead frame 110 and have been bonded to lead frame 110. This bonding has been performed in a single step as described above.

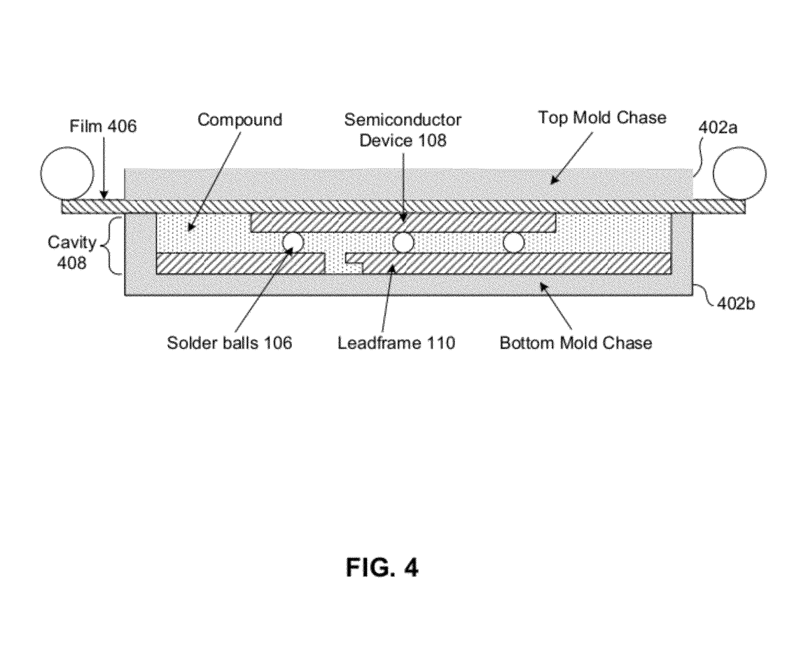

FIG. 4 depicts a more detailed example of molding manufacturing process according to one embodiment. A top mold chase 402a and a bottom mold chase 402b are used to encapsulate semiconductor device 108 with a molding compound 404.

Top mold chase 402 may have a flat surface. Top mold chase 402a is flat because the flip bond process is used. In this case, the bottom surface of semiconductor device 108 is facing the bottom surface of top mold chase 402. Thus, a flat surface is used.

The flat surface is covered by a film 406. In one embodiment, film 406 prevents a molding flash to occur where a thin layer of materials is forced out of a molding cavity. In this case, film covers the flat surface of top mold chase 402a. Bottom mold chase 402b is also coupled a portion of film 406. Bottom mold chase 402b may be in a U-shape or bucket-shape. The shape allows a cavity 408 to be formed. Bottom mold chase 402b couples to a bottom surface of lead frame 110 and also a side surface of lead frame 110.

Cavity 408 includes semiconductor device 108, solder balls 106, and lead frame 110. Molding compound 404 is then injected into cavity 408 to surround top surface 104b of semiconductor device 108 and also the top surface of lead frame 110.

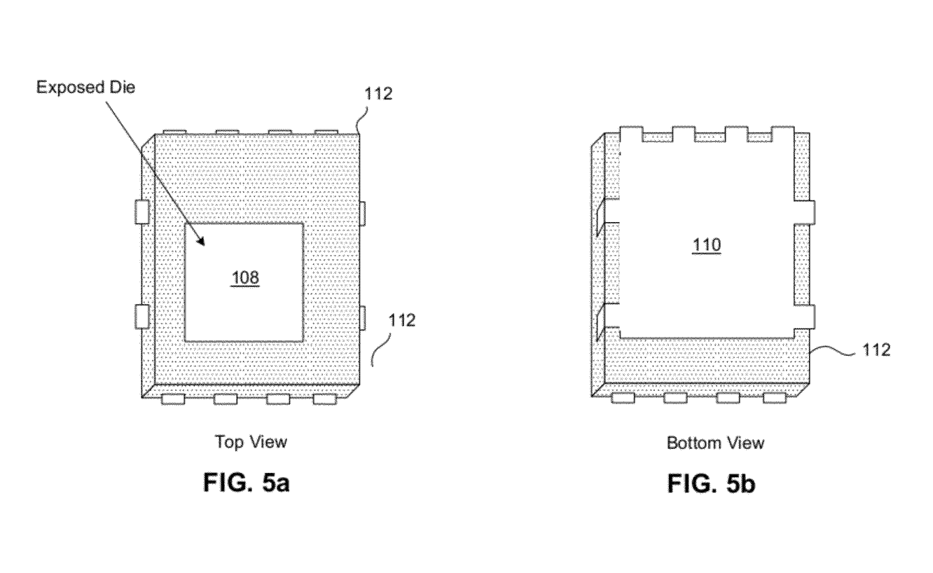

FIGS. 5a and 5b depict the trim and form manufacturing process in more detail according to one embodiment. FIG. 5a shows a top view of package 112 according to one embodiment. As shown, bottom surface 104a semiconductor device 108 is exposed on a top surface of package 112. This is because molding compound 404 was injected into cavity 408 to cover top surface 104b of semiconductor device 108 in addition to a side surface. However, molding compound 404 does not cover bottom surface 104a of semiconductor device 108. This exposes semiconductor device 108 from package 112.

FIG. 5b shows a bottom view of package 112 according to one embodiment. As shown, lead frame 110 is exposed from package 112. This exposes die pad 110.

FIG. 6 shows a side view of package 112 according to one embodiment. As shown, semiconductor device 108 is exposed on a top surface of package 112. Also, lead frame 110 is exposed on the bottom surface of package 112. Molding compound 404 encapsulates semiconductor device 108, solder balls 106, and lead frame 110.

Accordingly, particular embodiments use a flip bond to bond semiconductor device 108 and solder balls 106 to lead frame 110 in a single step. Also, the back side of semiconductor device 108 is exposed from package 112. This provides additional heat dissipation.

By adopting the method whereby the solder balls are directly bonded to lead frame 110, the resulting package has thinner walls, facilitating the release of heat energy towards the outside environment during chip operation; in addition, embodiments further combine the welding and routing steps into one step, shortening the process period. Adopting the method whereby solder balls are directly bonded to lead frame 110 replaces the use of metal lines (e.g. gold) to electrically connect the two together, and thus is capable of reducing the encapsulation resistance between the lead wire frame and the chip. Utilizing solder balls in place of metal lines shortens the lead wire separation between the chip and lead wire frame, avoiding creepage and crosstalk among the lead wires and the effect of external electromagnetic radiation on the working of the chip, and thus is particularly suited to the encapsulation of high frequency devices. Furthermore, the back surface of the chip is exposed on the outside of the plastic body, i.e. the heat source is in direct contact with air, which can improve the heat dissipation of the package and reduce encapsulation heat resistance. For power devices, this type of package is lighter and thinner, and in line with the trend of smaller, lighter and thinner packages. [0045] As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. Based on the above disclosure and the following claims, other arrangements, embodiments, implementations and equivalents may be employed without departing from the scope of the invention as defined by the claims.

What is claimed is:

1. A method for manufacturing a power semiconductor package, the method comprising:
attaching a plurality of solders balls onto a power semiconductor device;
bonding the plurality of solder balls onto a lead frame using a flip bond processing step, the flip bond processing step bonding the semiconductor device to the lead frame and interconnecting the lead frame to the semiconductor device in a single processing step; and
molding the semiconductor device, plurality of solder balls, and the lead frame to form the power semiconductor package, wherein semiconductor device is exposed on a first side of the semiconductor package.

2. The method of claim 1, further comprising:
attaching the plurality of solder balls onto a wafer; and
sawing the wafer to form the semiconductor device with the plurality of solder balls attached.

3. The method of claim 1, wherein wire bonding and die bonding are performed in the flip bond processing step.

4. The method of claim 1, wherein a top mold chase is used to mold the semiconductor package, wherein the top mold chase includes a flat surface that is facing the semiconductor device.

5. The method of claim 4, wherein the flat surface is facing a bottom surface of the semiconductor device.

6. The method of claim 4, further comprising placing a film in between the top mold chase and the semiconductor device.

7. The method of claim 6, wherein the film prevents molding flash.

8. The method of claim 4, wherein a bottom mold chase is placed beneath the lead frame to form a cavity in which encapsulation is injected to mold the semiconductor package.

9. The method of claim 8, wherein the bottom mold chase is in a shape to form the cavity.

10. The method of claim 1, further comprising trimming the semiconductor package to form a single semiconductor package.

11. The method of claim 1, wherein the lead frame is exposed on a second side of the semiconductor package.

12. The method of claim 1, wherein the plurality of solder balls are attached to a top side of the semiconductor device.

13. A method for manufacturing a power semiconductor package, the method comprising:
bonding the plurality of solder balls onto a lead frame using a flip bond processing step, the flip bond processing step bonding the semiconductor device to the lead frame and interconnecting the lead frame to the semiconductor device in a single step;
placing a first mold chase above a power semiconductor device, wherein the first mold chase has a flat surface facing a bottom surface of the semiconductor device;
placing a second mold chase below a bottom surface of a lead frame; and
inserting a molding compound in a cavity formed by the first mold chase and the second mold chase to encapsulate the semiconductor device, plurality of solder balls, and the lead frame to form a semiconductor package, wherein semiconductor device is exposed on a first side of the semiconductor package.

14. The method of claim 13, further comprising:
attaching the plurality of solder balls onto a wafer; and
sawing the wafer to form the semiconductor device with the plurality of solder balls attached.

15. The method of claim 13, wherein wire bonding and die bonding are performed in the flip bond processing step.

16. The method of claim 13, further comprising placing a film in between the top mold chase and the semiconductor device.

17. The method of claim 13, further comprising trimming the semiconductor package to form a single semiconductor package.

18. The method of claim 13, wherein the lead frame is exposed on a second side of the semiconductor package.

19. The method of claim 13, wherein the plurality of solder balls are attached to a top side of the semiconductor device.

20. The method of claim 13, wherein the bottom mold chase is in a shape to form the cavity.
